(19) United States
(12) Patent Application Publication
(10) Pub. No.: US 2025/0014895 A1
(43) Pub. Date: Jan. 9, 2025

(54) METHOD FOR DEPOSITING A LAYER ONTO A SUBSTRATE AND SEMICONDUCTOR PROCESSING APPARATUS

(71) Applicant: ASM IP Holding B.V., Almere (NL)

(72) Inventor: René Henricus Jozef Vervuurt, Leuven (BE)

(21) Appl. No.: 18/762,752

(22) Filed: Jul. 3, 2024

Related U.S. Application Data
(60) Provisional application No. 63/525,172, filed on Jul. 6, 2023.

(51) Int. Cl. H01L 21/02; C23C 16/02; C23C 16/44; C23C 16/455; C23C 16/50; C23C 16/56

(52) U.S. Cl. CPC H01L 21/02274; C23C 16/02; C23C 16/4408; C23C 16/45536; C23C 16/50; C23C 16/56; H01L 21/02211; H01L 21/02126; H01L 21/0214; H01L 21/02164; H01L 21/02167; H01L 21/0217

(57) ABSTRACT

This disclosure relates to a method for depositing a layer onto a substrate and a semiconductor processing apparatus. The semiconductor processing apparatus comprises a process chamber comprising a housing defining an inner volume of the process chamber and a plurality of process stations inside the inner volume for holding a substrate. The semiconductor processing apparatus further comprises a plurality of active species generators comprising at least a first active species generator configured to provide first active species to at least one or more first process stations of the plurality of process stations and a second active species generator configured to provide second active species to at least one or more second process stations of the plurality of process stations.

### CROSS-REFERENCE TO RELATED APPLICATIONS

This application claims priority to and the benefit of U.S. Provisional Application No. 63/525,172, filed Jul. 6, 2023, the entirety of which is incorporated by reference herein.

### TECHNICAL FIELD

The present disclosure generally relates to the field of semiconductor processing methods and systems, and to the field integrated circuit manufacture.

### BACKGROUND

The scaling of semiconductor devices, such as logic devices and memory devices, has led to significant improvements in the speed and density of integrated circuits. However, conventional device scaling techniques face significant challenges for future technology nodes. For example, one challenge has been finding suitable ways of filling gaps, such as recesses, trenches, vias, and the like, with a material without formation of gaps or voids.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

According to a first aspect, a method for depositing a layer onto a substrate is provided.

In an embodiment of the first aspect, the method for depositing a layer onto a substrate comprises providing a process chamber comprising a housing defining an inner volume of the process chamber and a plurality of process stations arranged inside the inner volume.

In an embodiment of the first aspect, the method for depositing a layer onto a substrate comprises forming a preliminary layer onto the substrate at one or more first process stations of the plurality of process stations, the process of forming a preliminary layer comprising exposing the substrate to first active species formed using a first active species generator.

In an embodiment of the first aspect, the method for depositing a layer onto a substrate comprises transforming the preliminary layer at one or more second process stations of the plurality of process stations separate from the one or more first process stations, the process of transforming the preliminary layer comprising exposing the preliminary layer to second active species formed using a second active species generator different from the first active species generator.

According to a second aspect, a semiconductor processing apparatus is provided.

In an embodiment of the second aspect, the semiconductor processing apparatus comprises a process chamber comprising a housing defining an inner volume of the process chamber and a plurality of process stations inside the inner volume for holding a substrate.

In an embodiment of the second aspect, the semiconductor processing apparatus comprises a plurality of active species generators comprising at least a first active species generator configured to provide first active species to at least one or more first process stations of the plurality of process stations and a second active species generator different from the first active species generator, the second active species generator configured to provide second active species to at least one or more second process stations of the plurality of process stations separate from the one or more first process stations.

In an embodiment of the second aspect, the semiconductor processing apparatus comprises a control unit configured to control at least the process chamber and the plurality of active species generators to deposit a layer onto a substrate by a method in accordance with the first aspect.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWINGS

A more complete understanding of the embodiments of the present disclosure may be derived by referring to the detailed description and claims when considered in connection with the following illustrative figures:

FIG. 1 schematically depicts a method for depositing a layer onto a substrate, and

FIG. 2 shows a semiconductor processing apparatus.

The illustrations presented herein are not meant to be actual views of any particular material, structure, or device, but are merely idealized representations that are used to describe embodiments of the disclosure. It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure. Furthermore, the connecting lines shown in the various figures are intended to represent examples of functional relationships and/or physical couplings between the various elements. Many alternative or additional functional relationship or physical connections may be present in the practical system, and/or may be absent in some embodiments.

### DETAILED DESCRIPTION

In this specification, a “process” may refer to a series of one or more steps, leading to an end result. Additionally, a “step” may refer to a measure taken in order to achieve one or more pre-defined end results. Generally, a process may be a single-step or a multistep process. Additionally, a process may be divisible to a plurality of sub-processes, wherein individual sub-processes of such plurality of sub-processes may or may not share common steps.

Throughout this disclosure, a “layer” or “film” may refer to a structure having a certain thickness formed on a surface. A layer can be continuous or discontinuous. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequences, and/or functions or purposes of the adjacent films or layers.

In this disclosure, a “substrate” may refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various structures, such as recesses, vias, lines, and the like formed within or on at least a portion of a layer of the substrate.

In this specification, a “chemical vapor deposition process” or “CVD process” may refer to a coating process, wherein one or more gaseous compounds decompose to deposit a layer onto a substrate. Further, a “cyclic chemical vapor deposition process” or “cyclic CVD process” may refer to a CVD process comprising sequentially and/or cyclically providing precursors, and/or reactants, and/or active species to deposit said layer onto said substrate.

Throughout this specification, an “atomic layer deposition process” or “ALD process” may refer to a cyclic CVD process, comprising purging a process station between provision of precursors, and/or reactants, and/or active species. Typically, purging may be accomplished by flushing said process station with an inert gas. Additionally or alternatively, an “atomic layer deposition process” or “ALD process” may refer to a cyclic CVD process suitable for or configured to deposit a conformal layer, e.g., a layer with a step coverage (SC) of at least 95%, or 99%, or about 100% for a feature with an aspect ratio (AR) of 3:1, or 5:1, or 10:1, onto a substrate. Further, a “temporal atomic layer process” or “temporal ALD process” may refer to an ALD process, wherein the process of purging a process station comprises a temporal purging step during which provision of precursors, and/or reactants, and/or active species is discontinued. Additionally or alternatively, a “temporal atomic layer process” or “temporal ALD process” may refer to an ALD process, wherein a substrate onto which a layer is deposited is held immobile during deposition.

Throughout this specification, a “process station” may refer to a location suitable for or configured to hold a substrate so that a process may be performed on the substrate. Additionally or alternatively, a process station may refer to a portion of a process chamber. Herein, a “process chamber” may refer to a chamber suitable for or configured to enable performing a process on a substrate. Additionally or alternatively, a process chamber may refer to a vacuum chamber within which a process may be performed. In some embodiments, individual process stations of a process chamber may be arranged in gas isolation from each other or configured to be in gas isolation from each other while one or more substrates are processed inside one or more of the individual process stations. In such embodiments, individual process stations of a process chamber may be arranged in gas isolation by way of physical barriers, and/or gas bearings, and/or gas curtains. In some embodiments, after or concurrently with the placement of a substrate in a process station, said process station may be arranged in gas isolation. In some embodiments, after a substrate has been processed in a process station, said process station may be brought out of gas isolation such that said substrate may be removed from the process station. Typically, a plurality of substrates may be placed in a shared intermediate space of a process chamber for moving individual substrates of said plurality of substrates from one process station to another.

In this specification, “active species” may refer to unstable molecular entities formed in plasma. Additionally or alternatively, active species may refer to ions and/or (free) radicals. Herein, an “ion” may refer to an atomic or molecular particle possessing a net electric charge, and/or a “radical” may refer to an atomic or molecular particle possessing an unpaired electron.

Further, an “active species generator” may refer a device suitable for or configured to form active species. Additionally or alternatively, an active species generator may refer to a device suitable for or configured to form and sustain plasma, for example, a non-thermal plasma or “cold plasma”. Additionally or alternatively, an active species generator may refer to a plasma source, such as a non-thermal plasma source, e.g., a capacitively coupled plasma (CCP) source, an inductively coupled plasma (ICP) source, or an electron cyclotron resonance (ECR) plasma source. In some embodiments, an active species generator may be configured to form plasma at least partly using radio waves (i.e., electromagnetic radiation with frequency less than or equal to 300 megahertz (MHz)) and/or microwaves (i.e., electromagnetic radiation with frequency in a range from 300 MHz to 300 gigahertz (GHz)). Typically, an active species generator may be implemented as a direct plasma generator, an indirect plasma generator, or a remote plasma generator.

Herein, “plasma” may refer at least partially ionized gas containing various types of particles, e.g., electrons, atoms, ions, molecules, and/or radicals. Typically, plasma may be electrically neutral as a whole.

In this specification, a “direct plasma generator” may refer to an active species generator configured to form and sustain plasma within a process chamber between a perforated faceplate of a showerhead injector of said process chamber and a substrate support of said process chamber, whereas an “indirect plasma generator” may refer to an active species generator configured to form and sustain plasma within a process chamber such that a perforated faceplate of a showerhead injector of said process chamber and/or a mesh plate suitable for or configured to block ions is arranged between said plasma and a substrate support of said process chamber. Further, a “remote plasma generator” may refer to an active species generator configured to form and sustain plasma outside of a process chamber and to introduce active species, e.g., radicals, formed in said plasma into said process chamber, for example, via an active species duct or channel.

In this disclosure, a “plasma-enhanced” deposition process may refer to a CVD process, wherein one or more gaseous compounds that decompose to deposit a layer are exposed to active species during said deposition process. Further, a “radical-enhanced” deposition process may refer to a CVD process, wherein one or more gaseous compounds that decompose to deposit a layer are exposed to radicals during said deposition process without being substantially exposed to ions.

Throughout this disclosure, an active species generator being “different from” another active species generator may refer to said another active species generator being categorizable to a set of active species generator categories and said active species being categorizable to at least one active species generator category distinct from said set of active species generator. Generally, an active species generator configured to provide active species to a process station may be categorized at least based on the physical phenomena used by said active species generator for forming plasma and/or active species and based on the position of plasma to be formed by said active species generator during processing of a substrate in a process chamber.

In this disclosure, “transforming” a layer may refer to exposing said layer to active species. Additionally or alternatively, transforming a layer may refer to modifying the microstructure, and/or nanostructure, and/or crystalline structure, e.g., crystallization, amorphization, and/or polymorphic transformation, of at least part of said layer. Additionally or alternatively, transforming a layer may refer to modifying the chemical composition, e.g., incorporation or removal of hydrogen, halogen(s), oxygen, nitrogen, and/or carbon, of at least part of said layer. Additionally or alternatively, transforming a layer may refer to modifying at least part of said layer without forming another layer over said layer. Additionally or alternatively, transforming a layer may refer to processing said layer such that one or more experimentally determinable parameters, such as density; and/or etch rate using a specific etching method; and/or one or more optical properties, e.g., absorption and/or emission spectra in the ultraviolet, visible, and/or near infrared parts of the electromagnetic spectrum, i.e., from approximately 100 nanometers (nm) to 10 micrometers (μm); and/or X-ray scattering properties, such as X-ray scattering intensities and/or angles; and/or elemental composition; and/or chemical state(s); and/or density of electronic states, of at least part of said layer may change. In some embodiments, such change(s) may be experimentally quantifiable, and/or statistically relevant, and/or greater than or equal to at least 0.1%, or at least 0.5%, or at least 1%, or at least 2%, or at least 5%, or at least 10%, or at least 20%.

Throughout this specification, a “control unit” may refer to any combination of individual controller devices and processing electronics that may be integrated with or connected to other devices. In some embodiments, a control unit may include a centralized controller that controls the operation of multiple devices or components. In some embodiments, a control unit may be understood to include a plurality of distributed controllers that control the operation of one or more devices or components. Generally, control sequences may be hardwired or programmed into a control unit. Memory devices of a control unit may include non-transitory computer-readable media, such as physical computer storage including hard drives, solid state memory, random access memory (RAM), read only memory (ROM), optical disc, volatile or non-volatile storage, combinations of the same and/or the like. Said non-transitory computer-readable media may provide instructions to one or more processors. It will be appreciated that the instructions may be for any of the actions described herein, such that processing of the instructions by the one or more processors causes the semiconductor processing apparatus to perform those actions.

The description of example embodiments of methods, structures, devices, and/or systems provided below is merely informative and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as example embodiments and may be recited in the dependent claims. Unless otherwise noted, the example embodiments or components thereof may be combined or may be applied separately.

Additionally, for the sake of brevity, conventional manufacturing, connection, preparation, and other functional aspects of the system may not be described in detail.

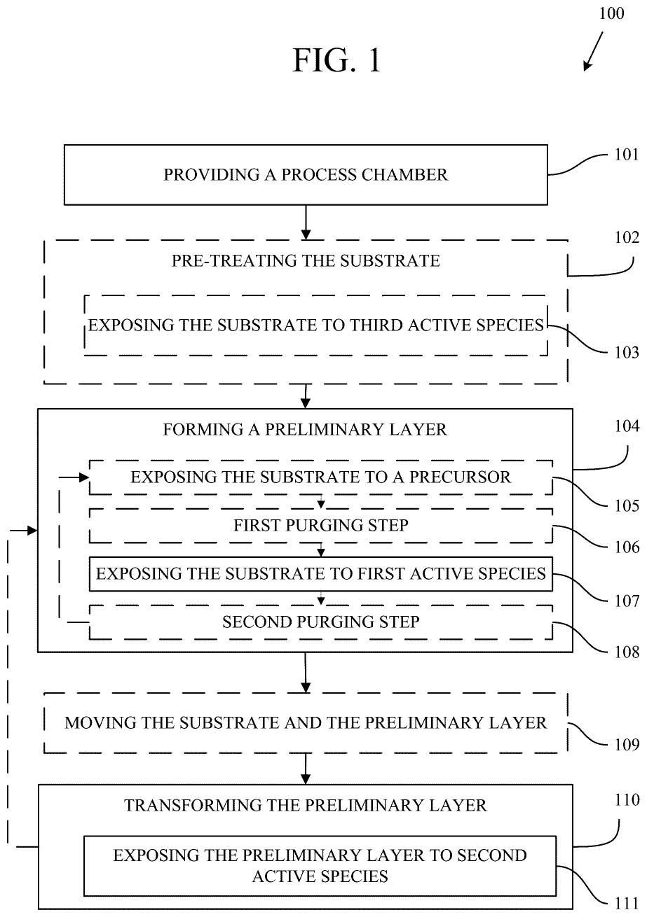

FIG. 1 schematically depicts a method 100 for depositing a layer onto a substrate according to an embodiment. In FIG. 1, optional features of the method 100 are depicted using dashed lines. In other embodiments, a method for depositing a layer onto a substrate may be identical, similar, or different from the method 100 of the embodiment of FIG. 1.

The method 100 of the embodiment of FIG. 1 comprises providing a process chamber 101 comprising a housing defining an inner volume of the process chamber and a plurality of process stations arranged inside the inner volume; forming a preliminary layer 104 onto the substrate at one or more first process stations of the plurality of process stations, the process of forming a preliminary layer 104 comprising exposing the substrate to first active species 107 formed using a first active species generator; and transforming the preliminary layer 110 at one or more second process stations of the plurality of process stations separate from the one or more first process stations, the process of transforming the preliminary layer 110 comprising exposing the preliminary layer to second active species 111 formed using a second active species generator different from the first active species generator. In other embodiments, a method for depositing a layer onto a substrate may or may not comprise one or more of such features. In some embodiments, a method for depositing a layer onto a substrate comprising such features may facilitate co-optimization of several processes of said method involving the utilization of active species.

The method 100 of the embodiment of FIG. 1 may be implemented as a method for at least partially filling a gap formed in the substrate. In other embodiments, a method for depositing a layer onto a substrate may be implemented in any suitable manner, for example, as a method for at least partially filling a gap formed in a substrate or as a method for depositing a layer onto a polished surface of a substrate. In some embodiments, a method for depositing a layer onto a substrate may be implemented as a method for depositing a layer onto a complex three-dimensional surface of a substrate.

In the embodiment of FIG. 1, the process of forming a preliminary layer 104 may be implemented as a temporal ALD process. In other embodiments, a process of forming a preliminary layer may be implemented as any suitable type of process. For example, in some embodiments, a process of forming a preliminary layer may be implemented as a chemical vapor deposition (CVD) process, for example, a cyclic CVD process, such as an atomic layer deposition (ALD) process, e.g., a temporal ALD process.

The process of forming a preliminary layer 104 of the embodiment of FIG. 1 may be implemented as a plasma-enhanced atomic layer deposition (PEALD) process or as a radical-enhanced atomic layer deposition (REALD) process. In other embodiments, a process of forming a preliminary layer may or may not be implemented as a plasma-enhanced deposition process, such as a plasma-enhanced CVD (PECVD) process or a plasma-enhanced ALD (PEALD) process; or radical-enhanced deposition process, such as radical-enhanced CVD (RECVD) process or a radical-enhanced ALD (REALD) process.

The layer of the embodiment of FIG. 1 may consist substantially of silicon (Si), and/or oxygen (O), and/or nitrogen (N), and/or carbon (C). In other embodiments, a layer may comprise, consist substantially of, or consist of any suitable element(s) or material(s), and the scope of the present disclosure may not necessarily be limited to any specific materials or material combinations. In some embodiments, a layer may comprise, consist substantially of, or consist of silicon (Si), and/or oxygen (O), and/or nitrogen (N), and/or carbon (C). For example, in some such embodiments, a layer may comprise, consist substantially of, or consist of stoichiometric and/or non-stoichiometric silicon oxide, silicon nitride, and/or silicon carbide; silicon oxynitride; silicon oxycarbide; silicon carbonitride; and/or silicon oxycarbonitride.

In the embodiment of FIG. 1, the first active species may comprise, for example, active species formed from helium (He) and those formed from nitrogen (N₂) and/or oxygen (O₂). In other embodiments, any suitable active species may be used for forming a preliminary layer, and the scope of the present disclosure may not necessarily be limited to any specific first active species. For example, in some embodiments, first active species may comprise noble-gas-containing; and/or halogen-containing, such as fluorine-containing, chlorine-containing, and/or bromine-containing; and/or oxygen-containing; and/or nitrogen-containing; and/or hydrogen-containing ions and/or radicals.

The second active species of the embodiment of FIG. 1 may comprise, for example, active species formed from helium (He), nitrogen (N₂), hydrogen (H₂), and/or oxygen (O₂). In other embodiments, any suitable active species may be used for transforming the preliminary layer, and the scope of the present disclosure may not necessarily be limited to any specific second active species. For example, in some embodiments, second active species may comprise noble-gas-containing; and/or halogen-containing, such as fluorine-containing, chlorine-containing, and/or bromine-containing; and/or oxygen-containing; and/or nitrogen-containing; and/or hydrogen-containing ions and/or radicals.

In the embodiment of FIG. 1, the preliminary layer may be exposed to the second active species during the process of exposing the preliminary layer to second active species for a treatment duration of approximately 10 seconds(s). Typically, longer treatment durations yield more noticeable changes in layer quality. In other embodiments, a preliminary layer may be exposed to second active species during the process of exposing the preliminary layer to second active species for any suitable treatment duration, for example, a treatment duration greater than or equal to 0.5 seconds(s), or to 1 s, or to 2 s, or to 3 s, or to 4 s, or to 5 s, or to 6 s, or to 7 s, or to 8 s, or to 9 s, or to 10 s and/or less than or equal to 5 minutes (min), or to 4 min, or to 3 min, or to 2 min, or to 1 min, or to 50 s, or to 40 s, or to 30 s, or to 25 s, or to 20 s.

The process of forming a preliminary layer 104 of the embodiment of FIG. 1 may comprise exposing the substrate to a precursor 105, and the processes of exposing the substrate to a precursor 105 and exposing the substrate to first active species 107 may be temporally fully separated. In other embodiments, wherein a process of forming a preliminary layer comprises exposing the substrate to a precursor, processes of exposing the substrate to a precursor and exposing the substrate to first active species may be implemented in any suitable manner. In some such embodiments, the processes of exposing the substrate to a precursor and exposing the substrate to first active species may occur simultaneously or be temporally at least partially, i.e., partially or fully, separated and/or have identical, similar, or different durations.

In the embodiment of FIG. 1, the process of forming a preliminary layer may comprise a first purging step 106 after exposing the substrate to a precursor 105 and a second purging step 108 after exposing the substrate to first active species 107. In other embodiments, a process of forming a preliminary layer may or may not comprise such a first purging step and/or such a second purging step.

As indicated in FIG. 1 using a dashed arrow extending from the second purging step 108 to the process of exposing the substrate to first active species 107, the processes of exposing the substrate to a precursor 105 and exposing the substrate to first active species 107 may be repeated during the process of forming a preliminary layer 104. In other embodiments, processes of exposing the substrate to a precursor and exposing the substrate to first active species may or may not be repeated.

In the embodiment of FIG. 1, the precursor may be, for example, hexamethyldisilazane. In other embodiments, any suitable precursor(s) may be used for forming a preliminary layer, and the scope of the present disclosure may not necessarily be limited to any specific precursor(s). For example, in some embodiments, a precursor may comprise a silylamine, such as hexamethyldisilazane, 1,1,3,3-tetramethyl-1,3-divinyldisilazane, or 1,1,3,3-tetramethyldisilizane; and/or an aminosilane, such as bis(diethylamino) silane, bis(dimethylamino) silane, hexaethylaminodisilane, tetraethylaminosilane, bis(tert-butylamino) silane, trimethylsilyldiethylamine, or bis(dimethylamino) dimethylsilane; and/or a silane, such as monosilane (SiH₄), disilane (Si₂H₆), trisilane (Si₃H₈); and/or a halogenated silane, such as dichlorosilane (SiCl₂H₂) or diiodosilane (SiI₂H₂); and/or a silicon halide, such as silicon tetraiodide (SiI₄), silicon tetrabromide (SiBr₄), silicon tetrachloride (SiCl₄), hexachlorodisilane (Si₂Cl₆), hexaiododisilane (Si₂I₆), octoiodotrisilane (Si₃I₈).

The method 100 of the embodiment of FIG. 1 may further comprise pre-treating the substrate 102 at one or more third process stations of the plurality of process stations separate from both the one or more first process stations and the one or more second process stations. The process of pre-treating the substrate 102 may comprise exposing the substrate to third active species 103 formed using a third active species generator different from the first active species generator and/or the second active species generator. In other embodiments, a method for depositing a layer onto a substrate may or may not comprise one or more of such features. In some embodiments, a method for depositing a layer onto a substrate comprising such features may facilitate optimization of a process of forming a preliminary layer.

In the embodiment of FIG. 1, the third active species may comprise fluorine-containing ions and/or radicals. In other embodiments, third active species may comprise any suitable type(s) of active species, for example, halogen-containing, such as fluorine-containing, chlorine-containing, and/or bromine-containing; and/or oxygen-containing; and/or nitrogen-containing; and/or hydrogen-containing ions and/or radicals.

The method 100 of the embodiment of FIG. 1 may further comprise moving the substrate and the preliminary layer 109 from the one or more first process stations to the one or more second process stations. In other embodiments, a method for depositing a layer onto a substrate may or may not comprise moving the substrate and the preliminary layer from one or more first process stations to one or more second process stations.

As indicated in FIG. 1 using a dashed arrow extending from the process of transforming the preliminary layer 110 to the process of forming a preliminary layer 104, the processes of forming a preliminary layer 104 and transforming the preliminary layer 110 of the embodiment of FIG. 1 may be repeated. In some embodiments, processes of forming a preliminary layer and transforming the preliminary layer of a method for depositing a layer onto a substrate being repeated may facilitate depositing a layer of higher thickness and of desired quality. In other embodiments, processes of forming a preliminary layer and transforming the preliminary layer may or may not be repeated.

It is to be understood that the methods described above are exemplary in nature, and that these specific embodiments are not to be considered in a limiting sense, because numerous variations are possible. The specific methods, processes, and steps described herein may represent one or more of any number of processing strategies. Thus, the various acts illustrated may be performed in the sequence illustrated, in other sequences, or omitted in some cases.

Above, mainly features and details associated with the first aspect are discussed. In the following, features and details associated with the second aspect are emphasized. What is stated above in relation to, for example, definitions, details, features, and/or ways of implementation, applies, mutatis mutandis, to the second aspect discussed below.

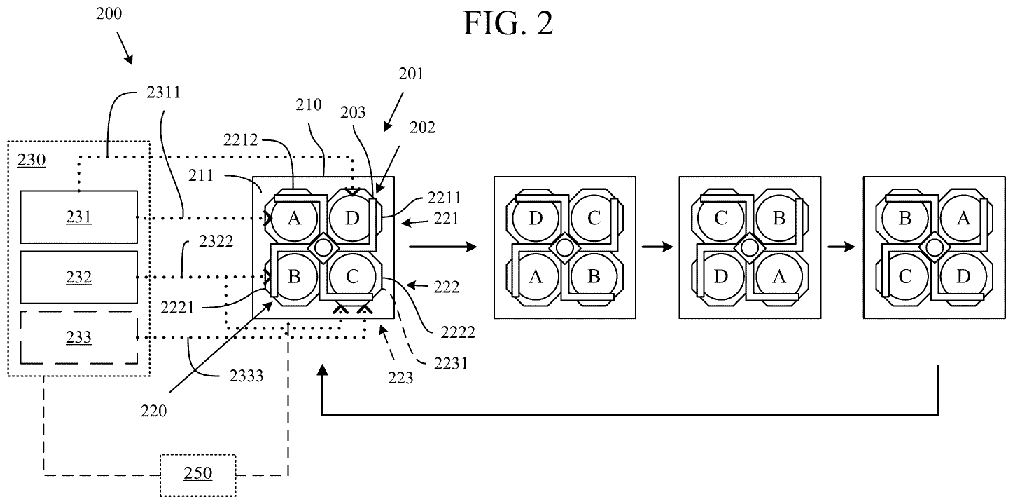

FIG. 2 schematically depicts a semiconductor processing apparatus 200 according to an embodiment. In other embodiments, a semiconductor processing apparatus may be identical, similar, or different from the semiconductor processing apparatus 200 of the embodiment of FIG. 2.

In the embodiment of FIG. 2, the semiconductor processing apparatus 200 comprises a process chamber 201 comprising a housing 210 defining an inner volume 211 of the process chamber 201 and inside the inner volume 211 a plurality of process stations 220 for holding a substrate. The semiconductor processing apparatus 200 also comprises a plurality of active species generators 230 comprising a first active species generator 231 configured to provide first active species 2311 to at least one or more first process stations 221 of the plurality of process stations 220 and a second active species generator 232 different from the first active species generator 231. The second active species generator 232 is configured to provide second active species 2322 to at least one or more second process stations 222 of the plurality of process stations 220 separate from the one or more first process stations 221. Further, the semiconductor processing apparatus 200 comprises a control unit 250 configured to control at least the process chamber 201 and the plurality of active species generators 230 to deposit a layer onto a substrate by a method in accordance with the first aspect.

In the embodiment of FIG. 2, the plurality of process stations 220 comprises a total of four process stations. In particular, the one or more first process stations 221 comprises two first process stations, a primary first process station 2211 and a secondary first process station 2212, and the one or more second process stations 222 comprises two second process stations, a primary second process station 2221, and a secondary second process station 2222. In other embodiments, a plurality of process stations, and/or one or more first process stations of said plurality of process stations, and/or one or more second process stations of said plurality of process stations may comprise any suitable numbers of process stations. For example, in some embodiments, a plurality of process stations may comprise a total of two to six process stations, and/or one or more first process stations of said plurality of process stations may comprise one to three first process stations, and/or one or more second process stations of said plurality of process stations may comprise one to three second process stations.

The semiconductor processing apparatus 200 of the embodiment of FIG. 2 may specifically be implemented as a Quad Chamber Module (QCM) suitable for or configured to be connected to a semiconductor manufacturing platform. Generally, a semiconductor processing apparatus may or may not be suitable for or configured to be connected to a semiconductor manufacturing platform. In other embodiments, wherein a semiconductor processing apparatus is suitable for or configured to be connected to a semiconductor manufacturing platform, said semiconductor processing apparatus may or may not be implemented as a QCM or as a Dual Chamber Module (DCM).

In some embodiments, a plurality of process stations may further comprise one or more third process stations separate from both one or more first process stations of said plurality of process stations and one or more second process stations of said plurality of process stations. In such embodiments, a plurality of active species generators may comprise a third active species generator different from a first active species generator of said plurality of active species generators and/or a second active species generator of said plurality of active species generators, the third active species generator configured to provide third active species to the one or more third process stations. For example, the secondary second process station 2222 of the embodiment of FIG. 2 could be replaced with one or more third process stations 223 comprising, for example, a single primary third process station 2231. In other embodiments, one or more third process stations of a plurality of process stations may comprise any suitable number of third process stations, e.g., one, two, or three third process stations.

In the embodiment of FIG. 2, the process chamber 201 comprises a substrate transfer unit 202 for moving a first substrate A, a second substrate B, a third substrate C, and a fourth substrate D between individual process stations of the plurality of process stations 220. As shown in FIG. 2 using arrows extending cyclically between different views of the process chamber 201, the substrate transfer unit 202 is configured to move the first substrate A, the second substrate B, the third substrate C, and the fourth substrate D anti-clockwise. In other embodiments, a process chamber may or may not comprise a substrate transfer unit for moving a substrate between individual process stations of a plurality of process stations. In embodiments, wherein a process chamber comprises such a substrate transfer unit, said substrate transfer unit may be configured to move said substrate in any suitable manner(s), for example, clockwise and/or anti-clockwise.

The substrate transfer unit 202 of the embodiment of FIG. 2 comprises a multi-arm substrate transfer member 203, commonly referred to as a “spider”, which is arranged centrally within the process chamber 201 and configured to engage with each individual process station of the plurality of process stations 220. In other embodiments, wherein a process chamber comprises a substrate transfer unit for moving a substrate between individual process stations of a plurality of process stations, said substrate transfer unit may or may not comprise such a multi-arm substrate transfer member. For example, in some embodiments, a substrate transfer unit may comprise a plurality of substrate transfer members, wherein each individual substrate transfer member of the plurality of substrate transfer members is configured to engage with a distinct subset of individual process stations of the plurality of process stations.

For example, after entering the process chamber 201 of the embodiment of FIG. 2 at the primary first process station 2211, the fourth substrate D may first undergo a process of forming a preliminary layer at the primary first process station 2211. Then, the fourth substrate D may be transferred to the secondary first process station 2212 to undergo another process of forming a preliminary layer, which may be identical, similar, or different from the previous process of forming a preliminary layer. The fourth substrate D may then be transferred consecutively to the primary second process station 2221 and the secondary second process station 2222 to undergo one or more processes of transforming the preliminary layer.

Alternatively, after entering the process chamber 201 of the embodiment of FIG. 2 at the primary first process station 2211 and the secondary first process station 2212, the fourth substrate D and the first substrate A may first undergo processes of forming a preliminary layer at the primary first process station 2211 and at the secondary first process station 2212, respectively. The fourth substrate D and the first substrate A may then be transferred to the primary second process station 2221 and the secondary second process station 2222, respectively, to undergo processes of transforming the preliminary layer.

In the embodiment of FIG. 2, individual process stations of the one or more first process stations, i.e., the primary first process station 2211 and the secondary first process station 2212, are arranged neighboring each other, and individual process stations of the one or more second process stations, i.e., the primary second process station 2221 and the secondary second process station 2222, are also arranged neighboring each other. Generally, such arrangement may enable performing the same or similar process on two or more substrates in parallel. In other embodiments, individual process stations of any type of process stations, e.g., those of one or more first process stations, one or more second process stations, or one or more third process stations, may be arranged in any suitable manner, for example, neighboring each other, separated from each another, or in two or more separated groups of neighboring process stations.

In the embodiment of FIG. 2, the first active species generator 231 may be implemented as a remote plasma generator or as an indirect plasma generator, and the second active species generator 232 may be implemented as a direct plasma generator. In such case, the first active species generator 231 may be further implemented as a capacitively coupled plasma (CCP) generator, and the second active species generator 232 may also be implemented as a CCP generator.

Alternatively, each of the first active species generator 231 and the second active species generator 232 of the embodiment of FIG. 2 may be implemented as a direct plasma generator. In such case, the first active species generator 231 may be further implemented as a capacitively coupled plasma (CCP) generator, and the second active species generator 232 may also be implemented as an inductively coupled plasma (ICP) generator.

Typically, a first active species generator being implemented as a remote plasma generator or as an indirect plasma generator may facilitate depositing layers of higher conformality. Additionally or alternatively, a first active species generator and/or second active species generator being implemented as a CCP generator may increase throughput of a process of transforming the preliminary layer. Additionally or alternatively, a second active species generator being implemented as an ICP generator may improve ion energy control during a process of transforming the preliminary layer, which may, in turn, increase throughput and/or yield more noticeable changes in layer quality.

In other embodiments, any individual active species generator, e.g., a first active species generator, or a second active species generator, or a third active species generator, may be implemented as any suitable type of active species generator, e.g., as a remote plasma generator, or as an indirect plasma generator, or as a direct plasma generator. In such other embodiments, said individual active species generator may be configured to form active species based on any suitable phenomenon or phenomena. As such, said any individual active species generator may be implemented, for example, as a capacitively coupled plasma (CCP) generator, or as an inductively coupled plasma (ICP) generator, or as an electron cyclotron resonance (ECR) plasma generator.

In other embodiments, wherein one of a first active species generator and a second active species generator is implemented as a remote plasma generator, or as an indirect plasma generator, or as a direct plasma generator, the other of the first active species generator and the second active species generator may or may not be implemented as any other of the remote plasma generator, the indirect plasma generator, and the direct plasma generator.

In some embodiments, wherein one of the first active species generator and the second active species generator is configured to form active species based on a first set of one or more physical phenomena, a second active species generator may or may not be configured to form active species based on a second set of one or more physical phenomena different from the first set of one or more physical phenomena. For example, in embodiments, wherein one of the first active species generator and the second active species generator is implemented as one of capacitively coupled plasma (CCP) generator, or as an inductively coupled plasma (ICP) generator, or as an electron cyclotron resonance (ECR) plasma generator, the other of the first active species generator and the second active species generator may or may not be implemented as any other of the CCP generator, the ICP generator, and the ECR plasma generator.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for depositing a layer onto a substrate, the method comprising:
providing a process chamber comprising a housing defining an inner volume of the process chamber and a plurality of process stations arranged inside the inner volume;
forming a preliminary layer onto the substrate at one or more first process stations of the plurality of process stations, the process of forming a preliminary layer comprising exposing the substrate to first active species formed using a first active species generator; and
transforming the preliminary layer at one or more second process stations of the plurality of process stations separate from the one or more first process stations, the process of transforming the preliminary layer comprising exposing the preliminary layer to second active species formed using a second active species generator different from the first active species generator.

2. The method according to any of claim 1, wherein the forming a preliminary layer is implemented as a chemical vapor deposition (CVD) process.

3. The method according to claim 1, wherein the process of forming a preliminary layer is implemented as a plasma-enhanced deposition process.

4. The method according to claim 1, the method at least partially filling a gap formed in the substrate.

5. The method according to claim 1, wherein the preliminary layer comprises, consists substantially of, or consists of silicon (Si), and/or oxygen (O), and/or nitrogen (N), and/or carbon (C).

6. The method according to claim 1, wherein the first active species comprises noble-gas-containing; and/or halogen-containing; and/or oxygen-containing; and/or nitrogen-containing; and/or hydrogen-containing ions and/or radicals.

7. The method according to claim 1, wherein the second active species comprises noble-gas-containing; and/or halogen-containing; and/or oxygen-containing; and/or nitrogen-containing; and/or hydrogen-containing ions and/or radicals.

8. The method according to claim 1, wherein the preliminary layer is exposed to the second active species is done by exposing the preliminary layer to the second active species for a treatment duration greater than or equal to 0.5 seconds(s) and/or less than or equal to 5 minutes (min).

9. The method according to claim 1, the method further comprising pre-treating the substrate at one or more third process stations of the plurality of process stations separate from both the one or more first process stations and the one or more second process stations, the process of pre-treating the substrate comprising exposing the substrate to third active species formed using a third active species generator different from the first active species generator and/or the second active species generator.

10. The method according to claim 9, wherein the third active species comprises halogen-containing; and/or oxygen-containing; and/or nitrogen-containing; and/or hydrogen-containing ions and/or radicals.

11. The method according to claim 1, wherein the forming a preliminary layer and transforming the preliminary layer are repeated.

12. The method according to claim 1, wherein the forming a preliminary layer further comprises exposing the substrate to a precursor.

13. The method according to claim 12, wherein the exposing the substrate to a precursor and the exposing the substrate to first active species are at least partially temporally separated.

14. The method according to claim 12, wherein the forming a preliminary layer further comprises a first purging step after the exposing the substrate to a precursor and/or a second purging step after the exposing the substrate to first active species.

15. The method according to claim 1, wherein the exposing the substrate to a precursor and the exposing the substrate to first active species are repeated during the forming of a preliminary layer.

16. The method according to claim 12, wherein the precursor comprises a silylamine; and/or an aminosilane; and/or a silane; and/or a halogenated silane; and/or a silicon halide.

17. The method according to claim 1, wherein the method further comprises moving the substrate and the preliminary layer from the one or more first process stations to the one or more second process stations.

18. A semiconductor processing apparatus comprising:
a process chamber comprising a housing defining an inner volume of the process chamber and a plurality of process stations inside the inner volume for holding a substrate;
a plurality of active species generators comprising at least a first active species generator configured to provide first active species to at least one or more first process stations of the plurality of process stations and a second active species generator different from the first active species generator, the second active species generator configured to provide second active species to at least one or more second process stations of the plurality of process stations separate from the one or more first process stations; and
a control unit configured to control at least the process chamber and the plurality of active species generators to deposit a preliminary layer onto a substrate by the method according to claim 1.

19. The semiconductor processing apparatus according to claim 18, wherein the plurality of process stations comprises a total of two to six process stations, and/or the one or more first process stations comprises a total of one to three first process stations, and/or the one or more second process stations comprises a total of one to three second process stations.

20. The semiconductor processing apparatus according to claim 18, wherein the plurality of process stations comprises one or more third process stations separate from both the one or more first process stations and the one or more second process stations, and the plurality of active species generators comprises a third active species generator different from the first active species generator and/or the second active species generator, the third active species generator configured to provide third active species to the one or more third process stations.
